(19) United States
(12) Patent Application Publication
(10) Pub. No.: US 2026/0342342 A1
(43) Pub. Date: Oct. 29, 2026

(54) FREQUENCY SYNTHESIZER SYSTEM BASED ON DUAL-BAND BANDWIDTH EXTENSION

(71) Applicant: The Hong Kong University of Science and Technology, Hong Kong (CN)

(72) Inventors: Yi LIU, Hong Kong (CN); Hanlin YANG, Hong Kong (CN); Zixi JING, Hong Kong (CN); Wen YANG, Hong Kong (CN); Howard Cam LUONG, Hong Kong (CN)

(21) Appl. No.: 19/641,578

(22) Filed: Apr. 8, 2026

Related U.S. Application Data
(60) Provisional application No. 63/796,334, filed on Apr. 28, 2025.

(51) Int. Cl. H03L 7/099; G01S 13/34; H03L 7/10

(52) U.S. Cl. CPC H03L 7/099; G01S 13/343; G01S 13/345; H03L 7/101

(57) ABSTRACT

A frequency synthesizer system is provided. The frequency synthesizer system includes a signal source, at least one mixer, at least one local oscillator, and a band combiner. The signal source generates a chirp signal having a limited tuning range. The mixer receives the chirp signal from the signal source and a local oscillator signal and performs frequency conversion on the chirp signal to generate a frequency-converted chirp signal. The local oscillator is configured to generate the local oscillator signal. The band combiner receives: a first chirp signal derived from the signal source without being processed by the mixer; and a second chirp signal generated by the mixer through frequency conversion of the chirp signal. The band combiner combines the first chirp signal and the second chirp signal to generate a combined output chirp signal having an extended effective bandwidth relative to the chirp signal generated by the signal source.

### CROSS-REFERENCE TO RELEVANT APPLICATIONS

The present application claims priority from a U.S. provisional patent application serial number 63/796,334 filed Apr. 28, 2025, and the disclosure of which are incorporated by reference in their entirety.

### TECHNICAL FIELD

The present invention relates to frequency synthesis technologies, and more particularly to a wideband chirp signal generation and processing system for high-frequency signal generation, which is applicable to ultra-wideband operation and supports improved linearity in frequency-modulated continuous-wave (FMCW) chirp signals through bandwidth extension techniques.

### BACKGROUND

FMCW frequency synthesizers are widely used in high-frequency sensing and ranging applications. As operating frequencies increase into the millimeter-wave and sub-terahertz regimes, there is an increasing demand for signal generation architectures capable of supporting wideband chirp generation with favorable frequency characteristics.

In high-frequency synthesis applications, one conventional approach for generating frequency-modulated chirp signals relies on digitally intensive signal generation techniques. Although such approaches may provide good control over chirp characteristics at relatively low frequencies, their achievable output frequency range and bandwidth are constrained by reference clock limitations and conversion circuitry, thereby limiting scalability toward millimeter-wave operation. Another commonly adopted approach employs phase-locked loop architectures incorporating voltage-controlled or digitally controlled oscillators. In such systems, increasing chirp bandwidth generally requires enlarging the tunable portion of the resonant tank. However, at high operating frequencies, parasitic effects increasingly dominate, resulting in an inherent trade-off between achievable bandwidth and carrier frequency.

Frequency multiplication techniques have also been used to extend signals into higher frequency bands. Although effective for frequency scaling, such techniques generally preserve the fractional bandwidth of the original signal source, thereby limiting the achievable absolute bandwidth at a given center frequency, particularly in millimeter-wave and sub-terahertz regimes. Certain architectures attempt to improve effective bandwidth through frequency translation or bandwidth-boosting techniques. Such approaches typically require additional frequency conversion stages to restore a desired carrier frequency, which introduces stringent bandwidth and linearity requirements and continues to pose implementation challenges at high frequencies.

Accordingly, there is a need for a wideband chirp signal generation system that facilitates effective bandwidth extension at high operating frequencies while maintaining favorable chirp characteristics.

### SUMMARY OF INVENTION

It is an objective of the present invention to provide systems and methods to address the aforementioned shortcomings and unmet needs in the state of the art.

Specifically, the present disclosure provides a wideband chirp signal generation and processing system configured to extend both fractional bandwidth and absolute bandwidth of chirp signal generation at high operating frequencies. The disclosed system employs bandwidth extension architectures that enable wideband operation while maintaining favorable chirp characteristics.

In accordance with a first aspect of the present invention, a frequency synthesizer system is provided. The frequency synthesizer system includes a signal source, at least one mixer, at least one local oscillator, and a band combiner. The signal source is configured to generate a chirp signal having a limited tuning range. The mixer is configured to receive the chirp signal from the signal source and a local oscillator signal, and to perform frequency conversion on the chirp signal to generate a frequency-converted chirp signal. The local oscillator is configured to generate the local oscillator signal supplied to the mixer. The band combiner is electrically coupled to receive: a first chirp signal derived from the signal source without being processed by the mixer; and a second chirp signal generated by the mixer through frequency conversion of the chirp signal. The band combiner is further configured to combine the first chirp signal and the second chirp signal to generate a combined output chirp signal having an extended effective bandwidth relative to the chirp signal generated by the signal source.

In accordance with a second aspect of the present invention, a wideband signal generation and processing system is provided. The wideband signal generation and processing system includes a plurality of frequency synthesizer systems as afore-described and a control module configured to control operation of the frequency synthesizer systems. The frequency synthesizer systems are selectively operated to generate one or more chirp signals in accordance with different operating modes or requirements.

In accordance with a third aspect of the present invention, a method of operating a frequency synthesizer system is provided. The method includes steps as follows: generating, by a signal source, a chirp signal having a limited tuning range; supplying the chirp signal along a first signal path directly to a band combiner as a first chirp signal without frequency conversion; supplying the chirp signal along a second signal path as the first input to a mixer; generating, by a local oscillator, a local oscillator signal as the second input to the mixer; performing, by the mixer, frequency conversion on the chirp signal using the local oscillator signal to generate a second chirp signal; and combining, by the band combiner, the first chirp signal and the second chirp signal to generate a combined output chirp signal having an extended effective bandwidth relative to the chirp signal generated by the signal source.

By the foregoing configuration, the present invention is capable of achieving at least the following technical effects.
(1) Unlike previous techniques such as direct-digital frequency synthesis, which are limited by the speed of digital circuitry and digital-to-analog conversion, the disclosed approach can operate at high frequencies, including millimeter-wave (~60 GHz) and sub-terahertz (>100 GHz) frequency ranges, since the RF signal is generated by an oscillator-based signal source rather than by digital signal generation circuits.
(2) The disclosed techniques enable expansion of both fractional bandwidth and absolute bandwidth in signal generation without significantly reducing a carrier frequency.
(3) In addition to widening bandwidth, the disclosed architectures further improve chirp linearity of the generated chirp signal.
(4) The disclosed bandwidth extension approach is extendable from a dual-band configuration to a multiple-band configuration to further optimize bandwidth and chirp linearity.

### BRIEF DESCRIPTION OF DRAWINGS

Embodiments of the invention are described in more details hereinafter with reference to the drawings, in which:

FIG. 1 is a conceptual diagram illustrating a dual-band bandwidth extension (BWE) principle for extending a chirp signal generated by a signal source having a limited tuning range, according to some embodiments of the present invention;

FIG. 2 is a block diagram illustrating a bandwidth extension system configured to produce an output chirp signal having an extended effective bandwidth;

FIG. 3 is a graphical illustration showing frequency deviation characteristics of a chirp signal at a band combiner output, demonstrating improvement in chirp linearity achieved by the bandwidth extension technique;

FIG. 4 is a block diagram illustrating a basic dual-band BWE architecture according to some embodiments of the present invention;

FIG. 5 is a block diagram illustrating a dual-band BWE system incorporating a phase correlator according to some embodiments of the present invention;

FIG. 6 is a block diagram illustrating a dual-band BWE system incorporating pre-frequency multiplication according to some embodiments of the present invention;

FIG. 7 is a block diagram illustrating a dual-band BWE system incorporating post-frequency multiplication according to some embodiments of the present invention;

FIG. 8 is a block diagram illustrating a dual-band BWE system incorporating pre-frequency multiplication, phase-correlated frequency conversion, and post-frequency multiplication according to some embodiments of the present invention;

FIG. 9 is a block diagram illustrating a multiple-band BWE system according to some embodiments of the present invention, in which a single signal source is reused across multiple mixers and local oscillators to generate a plurality of chirp bands;

FIG. 10 is a timing and frequency diagram illustrating a representative real-time frequency waveform generated by the multiple-band BWE system of FIG. 9;

FIG. 11 is a block diagram illustrating a multiple-band BWE system incorporating pre-frequency multiplication, phase-correlated local oscillator generation, and post-frequency multiplication according to some embodiments of the present invention;

FIG. 12 is a block diagram illustrating a multiple-band BWE system incorporating independent frequency scaling at inputs of mixers, local oscillator multiplication, and post-frequency multiplication according to some embodiments of the present invention;

FIG. 13 is a block diagram illustrating a multiple-band BWE system employing pipelined mixers to sequentially process a chirp signal across multiple frequency conversion stages according to some embodiments of the present invention;

FIG. 14 is a schematic diagram illustrating an example application of the proposed dual-band BWE technique in a chirp signal generation system;

FIG. 15 is a schematic diagram illustrating an example measurement and evaluation configuration for characterizing an output chirp signal;

FIG. 16 is a table illustrating a performance comparison between the bandwidth extension architecture of the present invention and representative sample implementations of other frequency synthesis and FMCW chirp generation approaches; and

FIG. 17 is a block diagram illustrating a wideband chirp signal generation and processing system according to some embodiments of the present invention.

### DETAILED DESCRIPTION OF THE INVENTION

In the following description, systems and methods using a frequency synthesizer based on dual-band bandwidth extension and the likes are set forth as preferred examples. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

In the present disclosure, the terms “electrically coupling” and “electrically coupled” encompass both wired electrical connections and wireless connections, and include communication links facilitating the transfer or exchange of data, signals, or control information.

As discussed above, existing solutions either struggle to operate effectively at high frequencies or fail to address the inherent trade-off between carrier frequency and fractional bandwidth (FBW). To address trade-offs among carrier frequency, fractional bandwidth, absolute bandwidth, and chirp linearity, the present disclosure provides a dual-band bandwidth extension (BWE) technique.

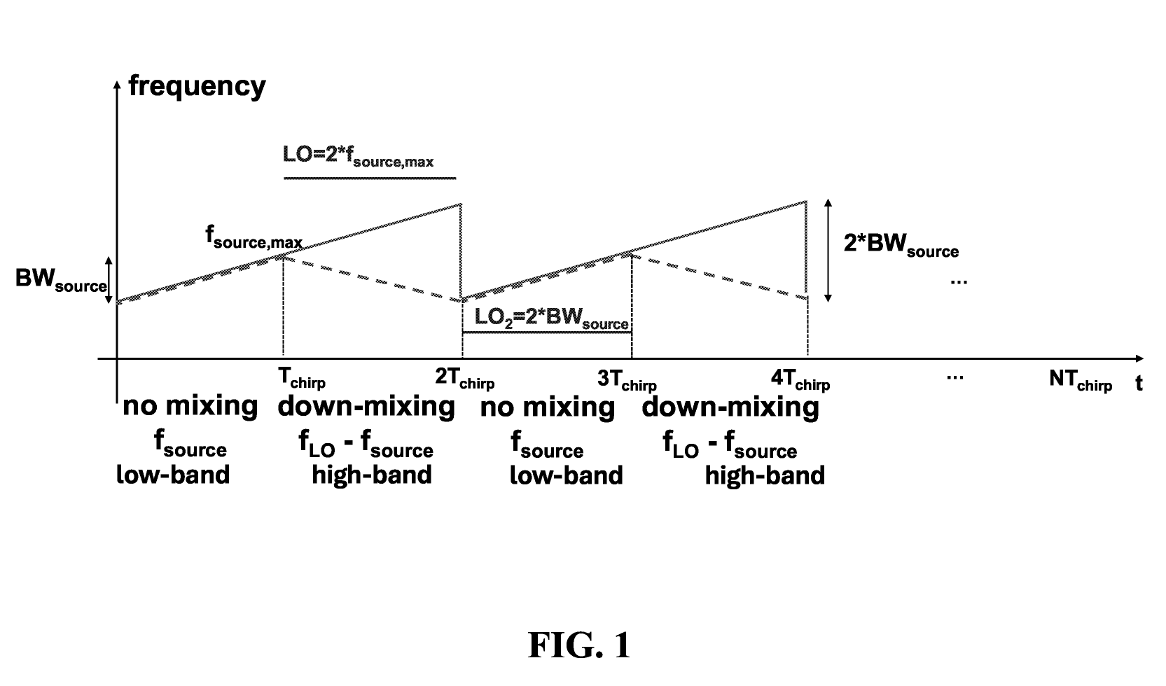

FIG. 1 shows an illustration of the proposed BWE technique according to some embodiments of the present invention. As shown in FIG. 1, a signal source with only a narrow chirp bandwidth BW_{source} is available. The frequency continuously sweeps up and down alternatively as a triangular waveform with the same chirp range. During the time from t = 0 to t = T_{chirp}, the signal source is directly connected to the output. To further extend the fractional bandwidth and absolute chirp bandwidth while not sacrificing the carrier frequency, another down-conversion mixer is adopted after the first up-chirp. The down-converted output f_{LO1} - f_{source} will continue to increase, with exactly the same chirp slope and polarity. Moreover, by accurately controlling the LO₁ frequency to be 2 times maximal frequency of the chirp signal source, the two chirps get seamlessly combined at t = T_{chirp} without introducing any frequency jump or gap. As a result, at the time point t = 2*T_{chirp}, the fractional bandwidth and absolute bandwidth have been doubled compared to the chirp signal source, while keeping slightly increased carrier frequency.

In the next step, the signal source starts to chirp up again and the output is switched to signal source again. The above dual-band BWE is repeated again to obtain the periodic chirp. Unlike certain existing approaches, the carrier frequency is even increased after bandwidth extension. Moreover, this BWE technique boosts fractional and absolute bandwidth simultaneously.

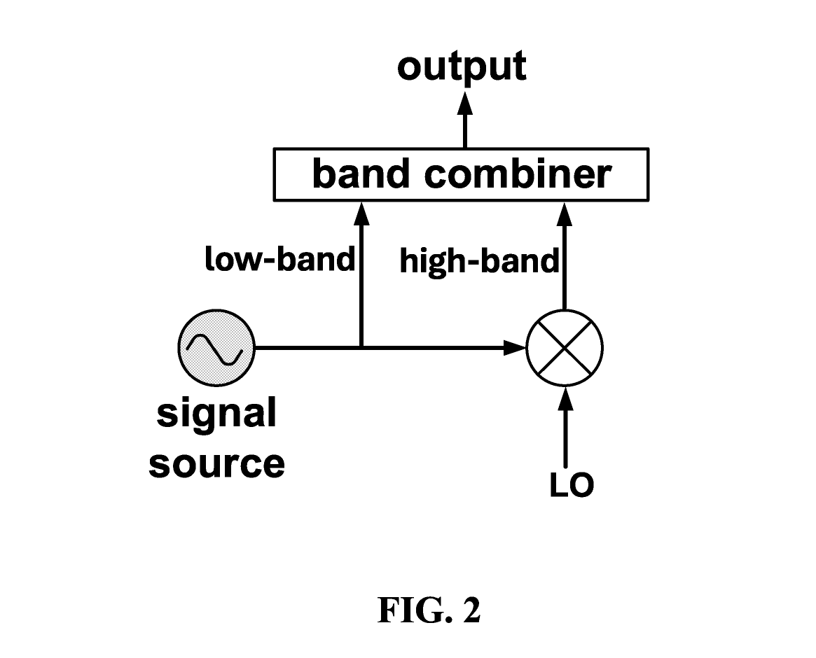

FIG. 2 shows a block diagram to implement a BWE system according to some embodiments of the present invention. The signal source is input to multiple mixers to perform either buffering or down-conversion. The outputs from the multiple mixers are combined together by a band combiner.

As shown in FIG. 2, the system includes a signal source configured to generate a chirp signal, a mixer coupled to receive a local oscillator (LO) signal, and a band combiner coupled to an output. The chirp signal generated by the signal source is provided along a first signal path as a low-band signal and along a second signal path to the mixer, where the chirp signal is frequency-converted using the LO signal to generate a high-band signal. The low-band signal and the high-band signal are combined by the band combiner to generate an output signal having an extended effective bandwidth.

In some embodiments, the BWE system shown in FIG. 2 is implemented using integrated-circuit (IC) design techniques and configured to support ultra-wide chirp bandwidth, high operational frequency, and favorable chirp linearity. By employing a dual-band bandwidth extension technique in which low-band and high-band chirp signals are combined, the system enables generation of wideband chirp signals suitable for high-frequency sensing applications, such as automotive and industrial radio detection and ranging (radar) systems, as well as augmented reality (AR) and virtual reality (VR) sensing systems. The extended bandwidth facilitates improved ranging resolution, while the enhanced chirp linearity contributes to improved ranging accuracy, and the high operational frequency allows utilization of wider available spectral resources.

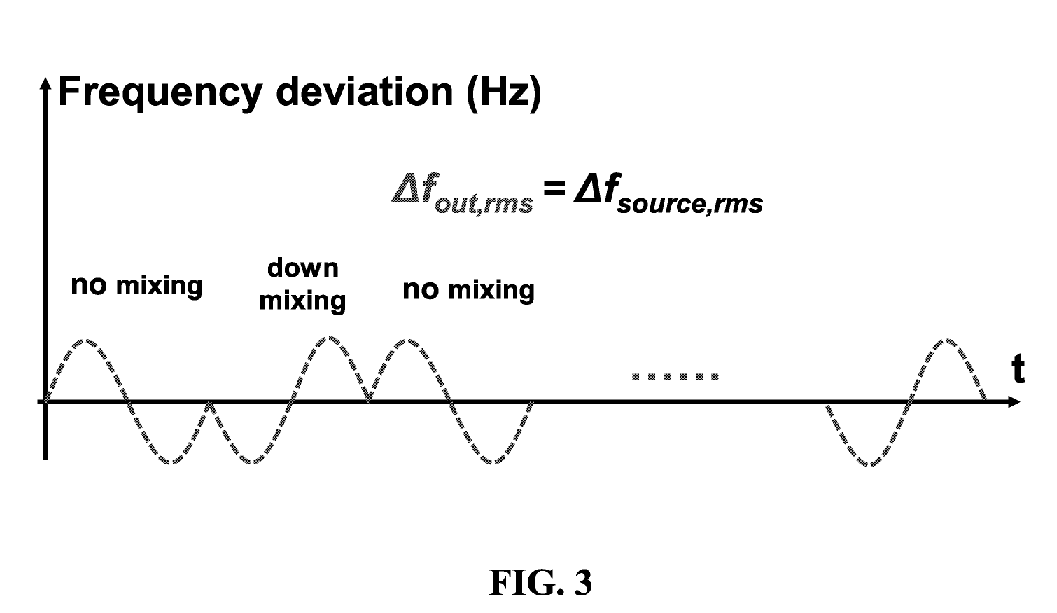

In addition to widening the chirp bandwidth of the chirp signal source, the proposed BWE also improves the chirp linearity which is quantified by the root-mean-square (rms) frequency deviation over the chirp bandwidth. FIG. 3 shows frequency deviation at the mux output according to some embodiments of the present invention. As shown in FIG. 3, the frequency deviation follows the shape of that of the chirp signal source while reversing the polarity during down mixing and maintaining the same during up mixing. As a result, the rms frequency deviation Δf out,rmsis kept the same as that of the chirp signal source, i.e., Δf source,rms. Noticing that the chirp bandwidth has been doubled at the final output, the chirp linearity is improved by N times.

In the following description, a series of schematic diagrams are provided to illustrate various embodiments of the proposed bandwidth extension architectures. Each schematic diagram depicts not only the functional elements included in a corresponding embodiment, but also representative interconnections among the elements. The illustrated interconnections are intended to indicate that the corresponding elements are coupled or operatively connected to one another for signal transfer, control, or communication purposes. Such couplings may be implemented by wired electrical connections, wireless communication links, or combinations thereof, depending on implementation requirements. It should be understood that the illustrated connections represent logical or functional relationships between elements, and do not limit the physical form, routing, or specific implementation of the interconnections in practice.

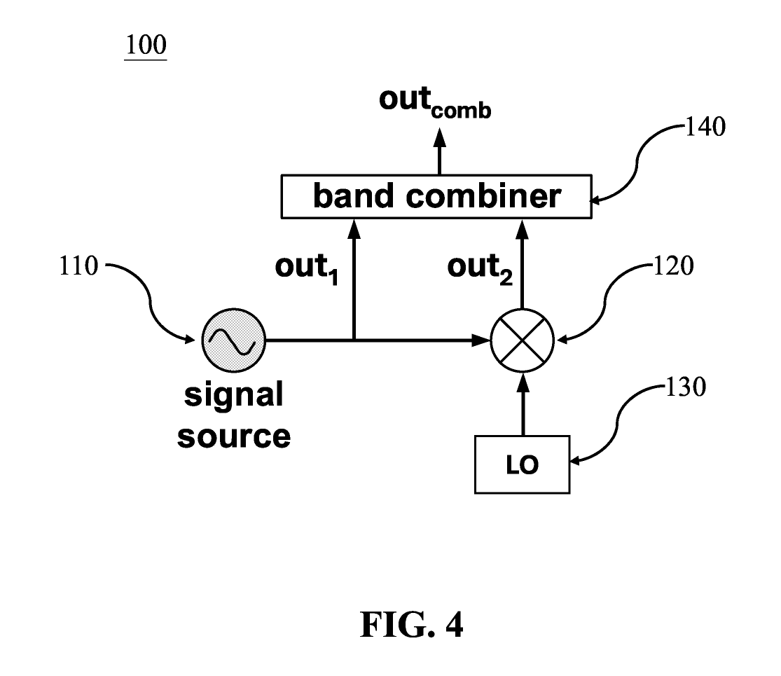

FIG. 4 shows a basic dual-band bandwidth extension (BWE) architecture for a dual-band BWE system 100 according to some embodiments of the present invention. The dual-band BWE system 100 includes a signal source 110, a mixer 120, a local oscillator (LO) 130, and a band combiner 140. The dual-band BWE system 100 is configured to extend an effective bandwidth of a chirp signal generated by a signal source having a limited tuning range, by generating and combining multiple frequency bands derived from the same signal source.

In the illustrated embodiment, the signal source 110 is electrically coupled to the band combiner 140 via a first signal path (e.g., out₁) and is further electrically coupled to the mixer 120 via a second signal path (e.g., out₂). The mixer 120 is electrically coupled to receive a local oscillator signal from the local oscillator 130. The band combiner 140 is electrically coupled to receive a first signal out₁ from the signal source 110 and a second signal out₂ from the mixer 120 and is further electrically coupled to an output node to provide a combined output signal out_{comb}. The electrical couplings described herein may be implemented by wired electrical connections, communication links, or combinations thereof.

The signal source 110 is configured to generate a base chirp signal, which forms a first output signal out₁. The first output signal out₁ is provided along a first signal path directly to the band combiner 140 and corresponds to a low-band chirp signal. The signal source 110 may be implemented using a voltage-controlled oscillator (VCO), a phase-locked loop (PLL), a direct digital frequency synthesizer (DDFS), or any combinations thereof. The frequency tuning range of the signal source 110 may be continuous or non-continuous, depending on implementation requirements.

The base chirp signal generated by the signal source 110 is further provided along a second signal path to the mixer 120. The mixer 120 may be implemented using an analog mixer, a passive mixer, an active mixer, or other frequency-conversion circuitry suitable for high-frequency operation.

The mixer 120 is coupled to receive a local oscillator signal from the local oscillator 130 and is configured to perform frequency conversion on the base chirp signal, thereby generating a second output signal out₂. In this configuration, the mixer 120 may be configured to reverse a down-chirp polarity of the base chirp signal and to produce a corresponding high-band chirp signal. The local oscillator 130 may be implemented using a VCO, a PLL, a frequency multiplier, a DDFS, or combinations thereof, and the local oscillator frequency may be fixed or tunable to facilitate bandwidth extension.

The first output signal out₁ and the second output signal out₂ are both provided to the band combiner 140. The band combiner 140 is configured to directly combine the low-band chirp signal and the high-band chirp signal to generate a combined output signal out_{comb}. By directly combining the unconverted output of the signal source 110 with the frequency-converted output generated by the mixer 120, the dual-band BWE system 100 achieves an extended effective tuning range and bandwidth without significantly reducing a carrier frequency.

In the basic dual-band BWE architecture described above, the low-band chirp signal and the high-band chirp signal are seamlessly combined within the band combiner 140 such that the combined output signal out_{comb} exhibits continuity in both time and frequency domains. This configuration enables simultaneous enhancement of fractional bandwidth (FBW) and absolute bandwidth (ABW), improves chirp linearity under fast chirp-rate operation, and relaxes design trade-offs associated with bandwidth and linearity constraints of the signal source 110.

In the foregoing configuration, the signal source 110, the mixer 120, the local oscillator 130, and the band combiner 140 do not operate independently, but are cooperatively arranged to form a system-level bandwidth extension mechanism. Specifically, an output of a single chirp signal source is concurrently utilized along an unconverted signal path and a frequency-converted signal path, and the resulting low-band and high-band chirp signals are subsequently combined in a coordinated manner. Through this cooperative operation, the system achieves simultaneous expansion of fractional bandwidth and absolute bandwidth while maintaining a high carrier frequency, improves chirp linearity under fast chirp-rate operation, and relaxes design constraints imposed on the signal source.

From a system architecture perspective, such technical effects are not achieved by merely optimizing individual circuit blocks, but arise from a specific configuration and interaction among the signal paths, frequency conversion operation, and band combination strategy. Conventional approaches typically attempt to address bandwidth and linearity limitations by increasing tuning range or performance of a single signal source, which inherently introduces trade-offs at high operating frequencies. In contrast, the disclosed architecture leverages coordinated use of multiple frequency bands derived from the same signal source and combines them in a manner that preserves chirp continuity. This system-level configuration provides a technical solution that would not be apparent from a straightforward aggregation of known components, thereby contributing to the inventive concept of the present disclosure.

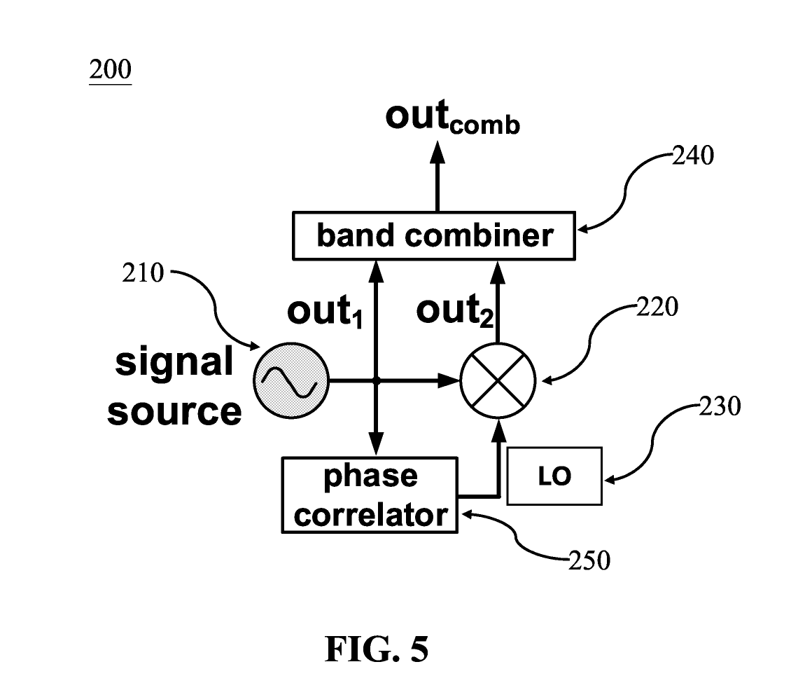

FIG. 5 illustrates a dual-band BWE system 200 according to some embodiments of the present invention, in which phase-noise cancellation is incorporated to further improve signal quality. The dual-band BWE system 200 includes a signal source 210, a mixer 220, a local oscillator 230, a band combiner 240, and a phase correlator 250. The overall architecture of the dual-band BWE system 200 is similar to the basic dual-band BWE scheme described with reference to FIG. 4, except that the phase correlator 250 is additionally coupled between the signal source 210 and the local oscillator 230 to establish a phase-correlated relationship therebetween.

In the illustrated embodiment, an output of the signal source 210 is provided along a first signal path as a low-band signal out₁ to the band combiner 240 and is further provided along a second signal path to the mixer 220 to generate a high-band signal out₂ through frequency conversion. The phase correlator 250 is electrically coupled to receive a signal derived from the signal source 210 and is configured to generate a phase-correlated control signal that is supplied to the local oscillator 230. Through this configuration, phase noise components associated with the signal source 210 are correlated with corresponding phase variations in the local oscillator signal, such that phase noise introduced during the frequency conversion process can be reduced or cancelled at the combined output.

In some embodiments, the phase correlator 250 may be implemented using a fractional frequency divider, an auxiliary signal source, or other phase correlation circuitry configured to derive a phase-related signal from the signal source 210. By incorporating the phase correlator 250 into the dual-band BWE architecture, the dual-band BWE system 200 improves phase noise performance of the combined output signal out_{comb} while maintaining the bandwidth extension characteristics achieved by the dual-band signal combination.

Specifically, the phase correlator 250 is configured to generate a phase-correlated control signal based on the base chirp signal produced by the signal source 210, and to provide the phase-correlated control signal to the local oscillator 230. Through this coordinated operation, phase variations associated with the signal source 210 are intentionally reflected in the local oscillator 230, such that phase noise components introduced during frequency conversion in the mixer 220 are correlated rather than independent. As a result, phase noise contributions from different signal paths are mitigated at the band combiner 240 when the low-band and high-band chirp signals are combined, without requiring direct modification of the chirp signal waveform or additional feedback control applied to the signal source 210.

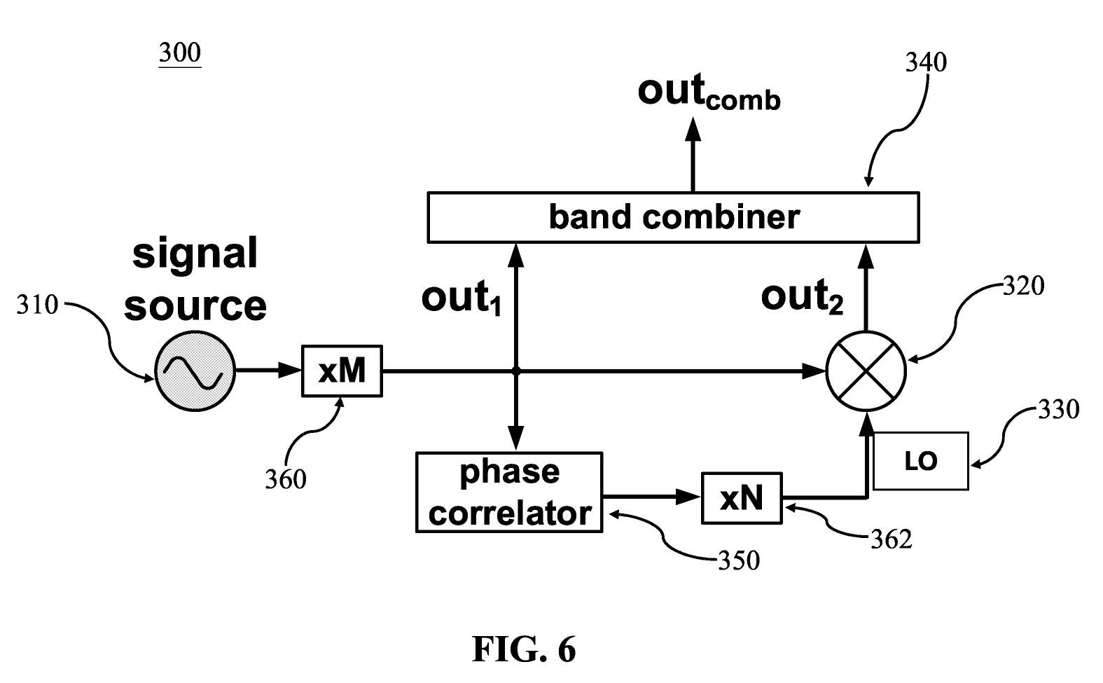

FIG. 6 illustrates a dual-band BWE system 300 according to some embodiments of the present invention, in which pre-frequency multiplication is incorporated into the dual-band BWE architecture to further extend an operating frequency range while preserving phase correlation. The dual-band BWE system 300 includes a signal source 310, a mixer 320, a local oscillator 330, a band combiner 340, a phase correlator 350, and one or more frequency multiplication elements 360 and 362.

In the illustrated embodiment, the signal source 310 is configured to generate a base chirp signal. Prior to being provided to the band combiner 340 as a low-band signal out₁, the base chirp signal is processed by a first frequency multiplication element 360, which multiplies a frequency of the base chirp signal by a factor M. The frequency-multiplied signal produced by the frequency multiplication element 360 forms the low-band output signal out₁ that is supplied to the band combiner 340. The frequency multiplication element 360 may be implemented using a frequency multiplier, a cascaded frequency multiplier chain, or other frequency scaling circuitry suitable for high-frequency operation.

The base chirp signal generated by the signal source 310 is further provided to the mixer 320 to generate a high-band signal out₂ through frequency conversion using a local oscillator signal generated by the local oscillator 330. In order to maintain phase correlation between the frequency-multiplied signal paths, the phase correlator 350 is electrically coupled to receive a signal derived from the signal source 310 and is configured to generate a phase-correlated control signal. The phase-correlated control signal is further processed by a second frequency multiplication element 362, which multiplies the control signal by a factor N before providing the resulting signal to the local oscillator 330. Through this configuration, phase variations associated with the signal source 310 are correspondingly reflected in the local oscillator signal even after frequency multiplication.

The high-band signal out₂ generated by the mixer 320 and the frequency-multiplied low-band signal out₁ are both provided to the band combiner 340. The band combiner 340 is configured to combine the low-band and high-band signals to generate a combined output signal out_{comb}. By introducing pre-frequency multiplication prior to signal combination, the dual-band BWE system 300 extends an effective carrier frequency of the combined output signal while preserving the dual-band bandwidth extension characteristics and phase noise correlation achieved by the architectures described with reference to FIGS. 4 and 5.

In this configuration, the frequency multiplication elements 360 and 362 cooperate with the phase correlator 350 to propagate phase-related characteristics of the signal source 310 through both the low-band and high-band signal paths. As a result, phase noise introduced by frequency multiplication and frequency conversion operations is correlated across the signal paths and mitigated at the band combiner 340, thereby improving phase noise performance of the combined output signal out_{comb} without requiring independent optimization of the signal source 310 at higher operating frequencies.

Further, the frequency multiplication factors M and N associated with the frequency multiplication elements 360 and 362, respectively, may be positive integers greater than one. The values of M and N may be selected independently and may be the same or different, depending on system design considerations such as target operating frequency, bandwidth extension range, and phase noise performance.

In some embodiments, M and N are selected to be equal, such that both the low-band signal path and the local oscillator signal path undergo substantially the same frequency scaling. Under such configuration, phase-related characteristics derived from the signal source 310 are proportionally preserved across the signal paths, which facilitates phase correlation when the low-band and high-band signals are subsequently combined.

In some embodiments, M and N are selected to be different. For example, M may be greater than N, or N may be greater than M, depending on frequency planning and system design requirements. Selecting different multiplication factors allows relative frequency scaling between the low-band signal path and the local oscillator signal path, thereby providing flexibility in extending an operating frequency range, relaxing frequency generation constraints of the local oscillator 330, or mitigating phase noise introduced during frequency conversion.

In some embodiments, M and N are not constrained to maintain a fixed proportional relationship. In such configurations, the phase correlator 350 cooperates with the frequency multiplication elements 360 and 362 to propagate phase-related variations of the signal source 310 through both signal paths, such that phase noise components remain correlated rather than independent even when the frequency scaling factors differ. Through this coordinated operation, the dual-band BWE system 300 achieves frequency extension and phase noise mitigation without requiring strict matching between the frequency multiplication factors.

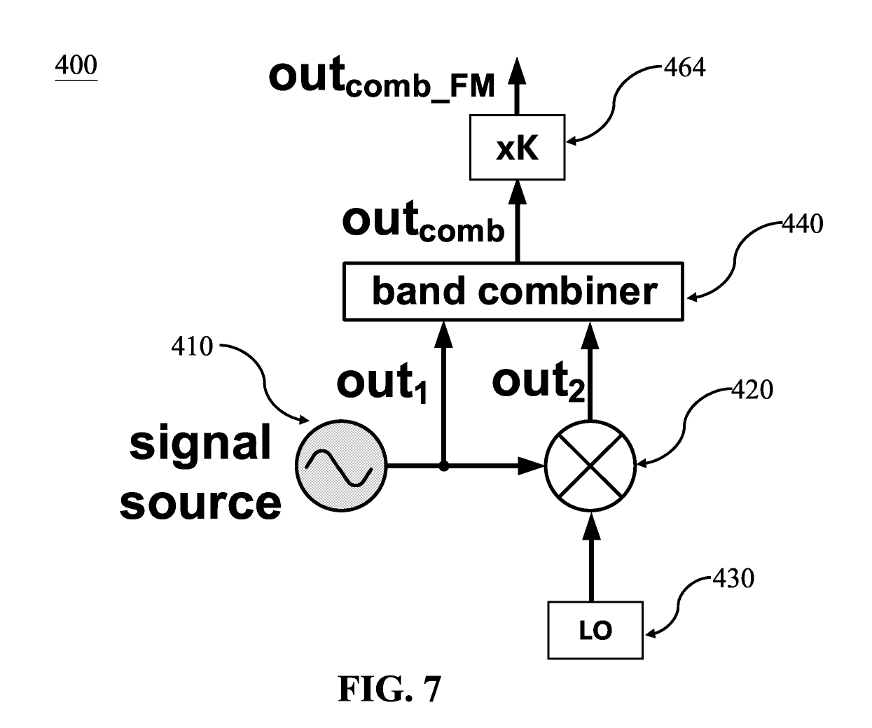

FIG. 7 illustrates a dual-band BWE system 400 according to some embodiments of the present invention, in which post-frequency multiplication is applied to a combined output of a dual-band BWE architecture. The dual-band BWE system 400 includes a signal source 410, a mixer 420, a local oscillator 430, a band combiner 440, and a frequency multiplication element 464 coupled to an output of the band combiner 440.

In the illustrated embodiment, the signal source 410 is configured to generate a base chirp signal. A first portion of the base chirp signal is provided along a first signal path as a low-band signal out₁ to the band combiner 440, while a second portion of the base chirp signal is provided along a second signal path to the mixer 420. The mixer 420 is coupled to receive a local oscillator signal from the local oscillator 430 and is configured to perform frequency conversion on the base chirp signal to generate a high-band signal out₂. The low-band signal out₁ and the high-band signal out₂ are provided to the band combiner 440 and combined to generate a combined output signal out_{comb}, in a manner similar to the dual-band BWE architecture described with reference to FIG. 4.

In the present embodiment, the combined output signal out_{comb} generated by the band combiner 440 is further provided to the frequency multiplication element 464. The frequency multiplication element 464 is configured to multiply a frequency of the combined output signal out_{comb} by a factor K to generate a frequency-multiplied output signal out_{comb}__{FM}. The frequency multiplication element 464 may be implemented using a frequency multiplier, a cascaded frequency multiplier chain, or other frequency scaling circuitry suitable for high-frequency operation.

By applying post-frequency multiplication after the low-band and high-band signals have been combined, the dual-band BWE system 400 increases an effective carrier frequency of the output signal without altering the dual-band bandwidth extension mechanism or the chirp continuity achieved by the band combiner 440. In this configuration, bandwidth extension is achieved at a lower frequency stage, while frequency scaling to a higher operating band is performed after signal combination. Such arrangement relaxes design constraints on the signal source 410, the mixer 420, and the local oscillator 430, and enables flexible deployment of the dual-band BWE architecture across different frequency bands.

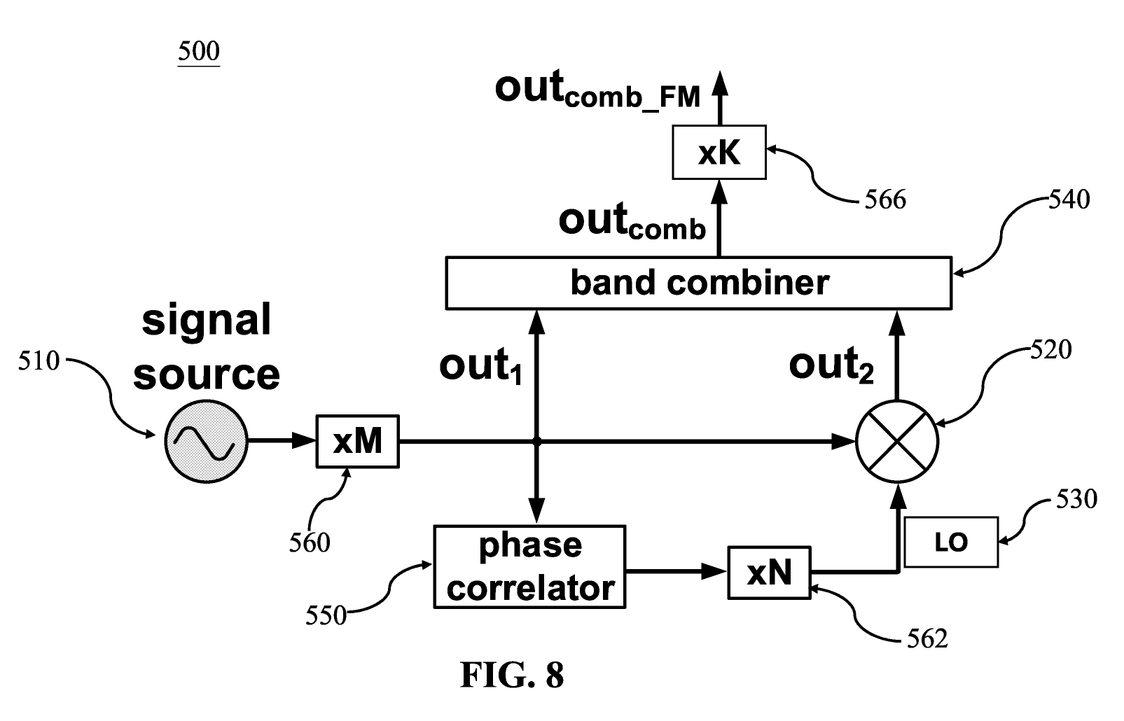

FIG. 8 illustrates a dual-band BWE system 500 according to some embodiments of the present invention, in which both pre-frequency multiplication and post-frequency multiplication are incorporated into a dual-band BWE architecture with phase correlation. The dual-band BWE system 500 includes a signal source 510, a mixer 520, a local oscillator 530, a band combiner 540, a phase correlator 550, a first frequency multiplication element 560, a second frequency multiplication element 562, and a third frequency multiplication element 566.

In the illustrated embodiment, the signal source 510 is configured to generate a base chirp signal. The base chirp signal is processed by the first frequency multiplication element 560, which multiplies a frequency of the base chirp signal by a factor M prior to signal distribution. A frequency-multiplied signal produced by the first frequency multiplication element 560 is provided along a first signal path as a low-band signal out₁ to the band combiner 540, and is further provided along a second signal path to the mixer 520 for frequency conversion.

The mixer 520 is coupled to receive a local oscillator signal generated by the local oscillator 530. To maintain phase correlation between the signal paths under frequency multiplication, the phase correlator 550 is electrically coupled to receive a signal derived from the signal source 510 and is configured to generate a phase-correlated control signal. The phase-correlated control signal is processed by the second frequency multiplication element 562, which multiplies the control signal by a factor N before supplying the resulting signal to the local oscillator 530. Through this configuration, phase-related variations of the signal source 510 are propagated to the local oscillator signal even after frequency multiplication.

The mixer 520 performs frequency conversion on the frequency-multiplied signal to generate a high-band signal out₂, which is provided to the band combiner 540 together with the low-band signal out₁. The band combiner 540 is configured to combine the low-band and high-band signals to generate a combined output signal out_{comb} exhibiting extended bandwidth and chirp continuity.

In this embodiment, the combined output signal out_{comb} is further processed by the third frequency multiplication element 566, which multiplies a frequency of the combined output signal by a factor K to generate a frequency-multiplied output signal out_{comb}__{FM}. The third frequency multiplication element 566 may be implemented using a frequency multiplier, a cascaded frequency multiplier chain, or other frequency scaling circuitry suitable for high-frequency operation.

By jointly incorporating pre-frequency multiplication, phase-correlated frequency conversion, and post-frequency multiplication, the dual-band BWE system 500 extends both an effective bandwidth and an operating frequency range of the output signal while preserving phase noise correlation across signal paths. This combined architecture provides enhanced flexibility in frequency planning, relaxes design constraints on the signal source 510 and the local oscillator 530, and enables scalable deployment of the dual-band BWE technique across a wide range of high-frequency and millimeter-wave applications.

In some embodiments, the frequency multiplication factors M, N, and K associated with the frequency multiplication elements 560, 562, and 566, respectively, are positive integers greater than one. The values of M, N, and K may be independently selected and are not required to be identical. Selection of the multiplication factors may be based on system-level considerations including target carrier frequency, bandwidth extension range, phase noise performance, implementation complexity, and available frequency generation resources.

In some embodiments, the multiplication factor K applied to the combined output signal is selected independently of M and N. Applying post-frequency multiplication after low-band and high-band signal combination allows bandwidth extension and chirp continuity to be achieved at a lower frequency stage, while subsequent frequency scaling is used to translate the combined signal to a higher operating frequency band. This configuration reduces design constraints on the signal source, mixer, and local oscillator, and facilitates deployment of the dual-band BWE architecture across millimeter-wave and sub-terahertz frequency ranges.

In one embodiment, K may be selected to be greater than M and N, such that the majority of frequency scaling is performed after signal combination. This arrangement is suitable for applications requiring ultra-high carrier frequencies while maintaining manageable phase noise and circuit complexity in the front-end stages. In other embodiments, K may be selected to be smaller than M and/or N, allowing frequency scaling to be distributed across multiple stages to balance phase noise accumulation, power consumption, and hardware complexity.

Through coordinated selection of the multiplication factors M, N, and K, the dual-band BWE system 500 provides a flexible frequency scaling framework in which bandwidth extension, phase correlation, and carrier frequency translation are jointly optimized at a system level. Rather than relying on a single frequency multiplication stage, distributing frequency scaling across pre-multiplication, phase-correlated frequency conversion, and post-multiplication stages allows phase noise contributions to remain correlated across signal paths and mitigated at the band combiner. This distributed approach improves scalability of the dual-band BWE architecture, relaxes design trade-offs of individual circuit blocks, and enables efficient realization of wideband, high-linearity chirp signals at high operating frequencies.

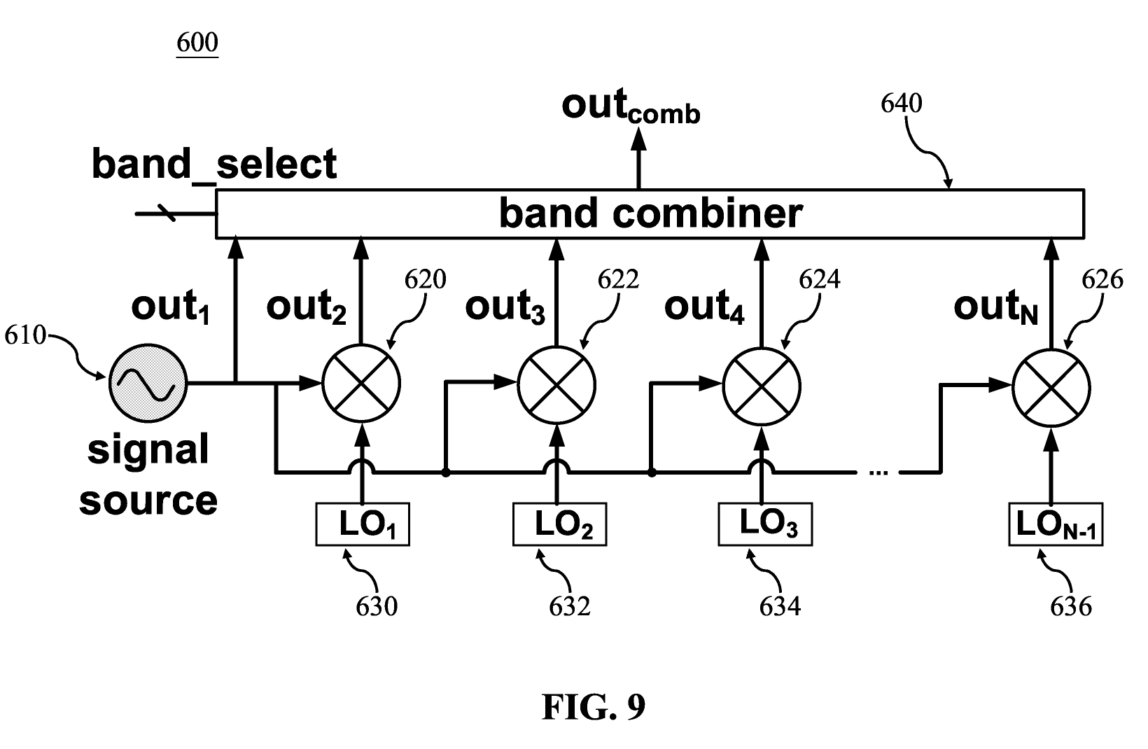

FIG. 9 illustrates a multiple-band BWE system 600 according to some embodiments of the present invention, in which a bandwidth extension technique is generalized from a dual-band configuration to a multiple-band configuration. The multiple-band BWE system 600 includes a signal source 610, a plurality of mixers 620, 622, 624, and 626, a corresponding plurality of local oscillators (LO₁, LO₂, LO₃, …, LO_{N-1}) 630, 632, 634, and 636, and a band combiner 640 configured to generate a combined output signal out_{comb}.

In the illustrated embodiment, the signal source 610 is configured to generate a base chirp signal, which forms a first output signal out₁. The base chirp signal is reused multiple times by being selectively provided to different mixers during different time intervals. Each of the mixers 620, 622, 624, and 626 is coupled to receive the base chirp signal from the signal source 610 and a corresponding local oscillator signal (e.g., LO₁, LO₂, LO₃, …, LO_{N-1}). Through frequency conversion, each mixer generates a respective output signal out₂, out₃, out₄, …, out_{N}, each corresponding to a different frequency band.

The mixers 620, 622, 624, and 626 are configured to perform up-conversion or down-conversion during different time intervals such that the output signals out₁ through outₙ collectively form a continuous sweeping chirp signal when combined. By appropriately scheduling activation of the mixers and selecting frequencies of the local oscillators, adjacent chirp segments are arranged to be contiguous in frequency and time domains, thereby avoiding frequency discontinuities or gaps between successive bands.

The band combiner 640 is electrically coupled to receive the output signals out₁ through outₙ and is configured to combine the multiple band signals into the combined output signal out_{comb}. In some embodiments, the band combiner 640 further receives a band selection control signal band_select, which is configured to control selection, ordering, or weighting of the individual band signals during combination. Through this configuration, the band combiner 640 provides flexible assembly of multiple chirp segments into a wideband output signal.

By extending the dual-band BWE architecture to a multiple-band configuration, the multiple-band BWE system 600 achieves scalable bandwidth extension using a single signal source 610 and multiple frequency conversion paths. This architecture enables reuse of the signal source across multiple frequency bands, distributes frequency conversion operations over time, and allows generation of ultra-wideband chirp signals without requiring a single signal source to directly support the entire bandwidth. Such multiple-band BWE configuration further improves scalability of the bandwidth extension technique and facilitates implementation across a wide range of high-frequency and millimeter-wave applications.

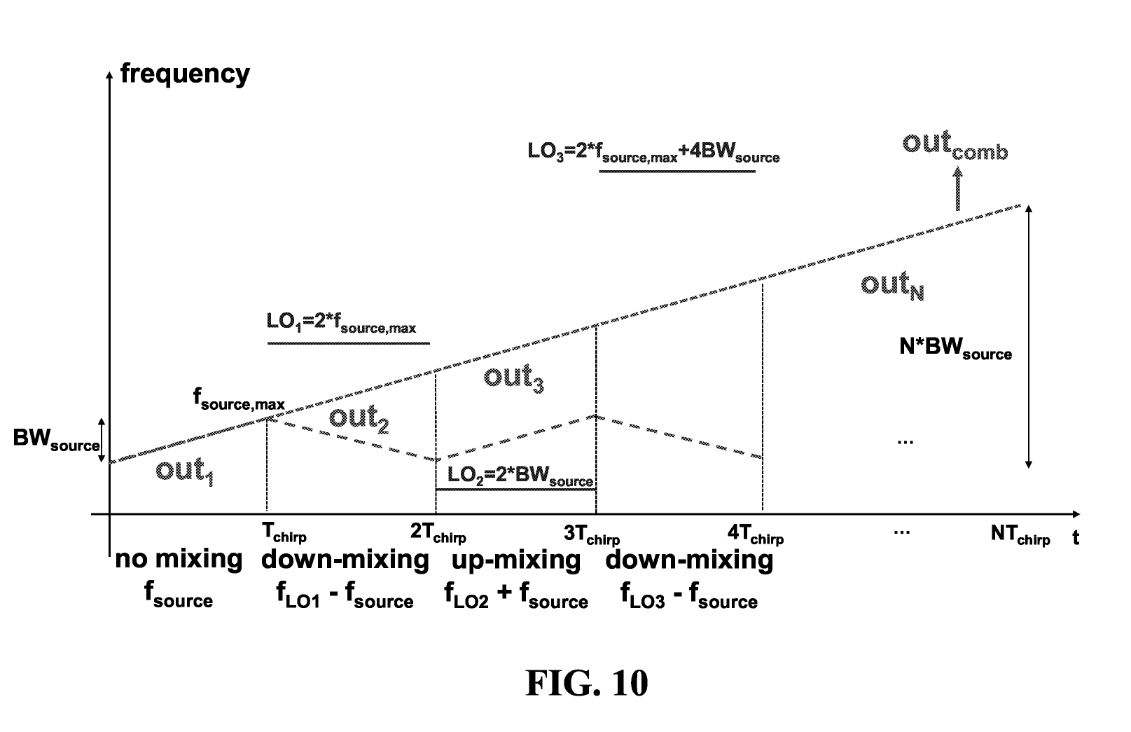

Specifically, FIG. 10 illustrates a representative real-time frequency waveform of the combined output signal generated by the multiple-band BWE architecture shown in FIG. 9. In this illustration, the waveform depicts how the signal source 610, the plurality of mixers 620, 622, 624, 626, the corresponding local oscillators 630, 632, 634, 636, and the band combiner 640 cooperatively operate over successive time intervals to produce a continuous wideband chirp signal.

As shown in FIG. 10, a base chirp signal generated by the signal source is reused across multiple frequency conversion paths. During different time intervals, the base chirp signal is selectively processed by different mixers operating with different local oscillator frequencies to generate successive output segments out₁, out₂, out₃, …, out_{N}. Each output segment corresponds to a distinct frequency band and occupies a respective chirp period. By appropriately selecting the frequencies of the local oscillators and controlling the timing of up-conversion and down-conversion operations, adjacent output segments are arranged to be contiguous in both time and frequency domains.

The band combiner 640 combines the successive output segments generated by the mixers into a single combined output signal out_{comb}. As a result of this coordinated operation, the combined output signal exhibits a continuous chirp waveform with a monotonically varying frequency, and an effective bandwidth that increases proportionally with the number of combined bands. Specifically, successive chirp segments corresponding to different frequency conversion paths are temporally arranged to occupy adjacent chirp periods and are frequency-aligned at their boundaries, such that the combined output spans an aggregated bandwidth corresponding to multiple instances of the source bandwidth. In this manner, a wideband chirp extending over multiple chirp periods is generated in real time without requiring the signal source to directly support the entire bandwidth.

Accordingly, FIG. 10 demonstrates the technical effect achieved by the multiple-band BWE architecture of FIG. 9, namely, the generation of an ultra-wideband and continuous chirp signal using a single signal source and multiple time-interleaved frequency conversion paths.

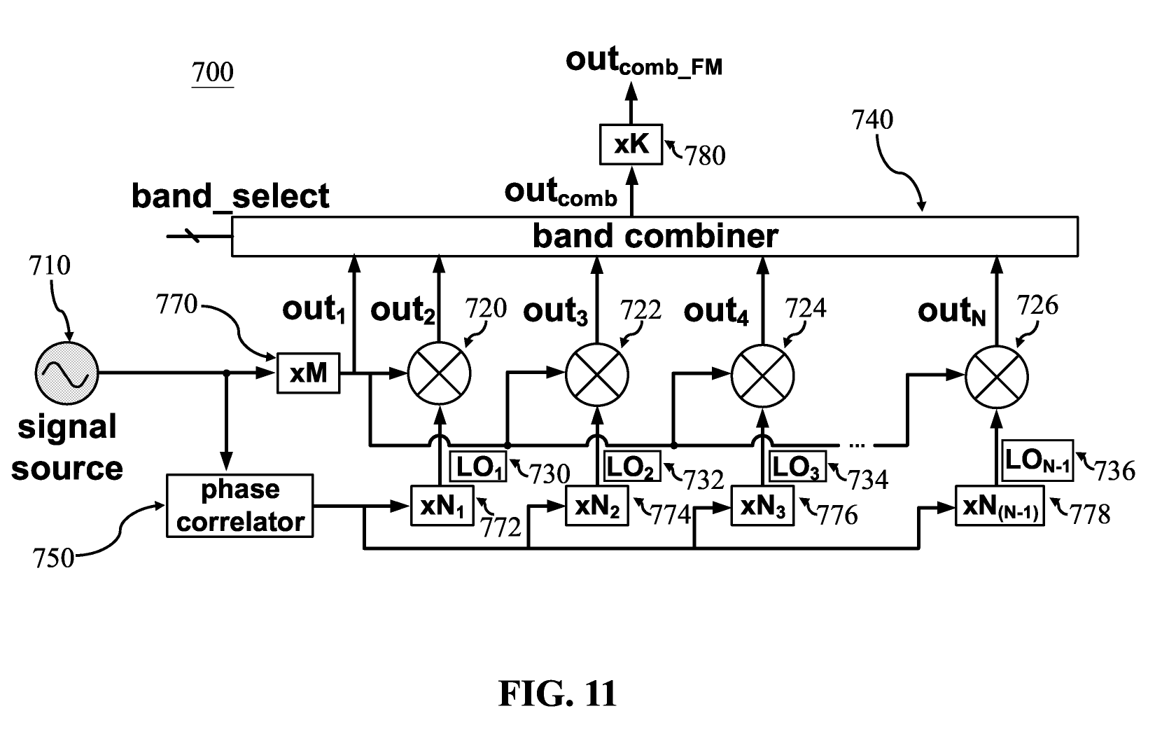

FIG. 11 illustrates a multiple-band BWE system 700 according to some embodiments of the present invention, in which pre-frequency multiplication, phase-correlated local oscillator generation, and post-frequency multiplication are jointly incorporated into a scalable multiple-band architecture. The multiple-band BWE system 700 includes a signal source 710, a plurality of mixers 720, 722, 724, and 726, a corresponding plurality of local oscillators (LO₁, LO₂, LO₃, …, LO_{N-1}) 730, 732, 734, and 736, a band combiner 740, a phase correlator 750, a first frequency multiplication element 770 associated with the signal source, a plurality of second frequency multiplication elements 772, 774, 776, and 778 associated with the local oscillators, and a third frequency multiplication element 780 coupled to an output of the band combiner 740.

In the illustrated embodiment, the signal source 710 is configured to generate a base chirp signal. The base chirp signal is processed by the first frequency multiplication element 770, which multiplies the frequency of the base chirp signal by a factor M prior to distribution. A frequency-multiplied signal produced by the first frequency multiplication element 770 forms a low-band signal out₁ that is supplied to the band combiner 740 and is further reused as an input to the plurality of mixers 720, 722, 724, 726.

Each of the mixers 720, 722, 724, and 726 is coupled to receive the frequency-multiplied signal from the signal source path and a corresponding local oscillator signal (i.e., LO₁, LO₂, LO₃, …, LO_{N-1}). The local oscillator signals are generated based on phase-correlated control signals derived from the phase correlator 750. Specifically, the phase correlator 750 is electrically coupled to receive a signal derived from the signal source 710 and is configured to generate phase-related control signals that are processed by the second frequency multiplication elements 772, 774, 776, and 778. Each of the second frequency multiplication elements applies a respective multiplication factor N₁, N₂, N₃, …, N_{N-1} to generate a corresponding local oscillator signal (i.e., LO₁, LO₂, LO₃, …, LO_{N-1}), such that phase-related variations of the signal source 710 are propagated to each local oscillator path.

The mixers 720, 722, 724, 726 are configured to perform frequency conversion on the frequency-multiplied signal during different time intervals, thereby generating a plurality of output signals out₂, out₃, out₄, …, out_{N} corresponding to different frequency bands. The band combiner 740 is electrically coupled to receive the low-band signal out₁ and the plurality of frequency-converted signals out₂, out₃, out₄, …, out_{N}, and is configured to combine the signals into a combined output signal out_{comb}. In some embodiments, the band combiner 740 further receives a band selection control signal band_select, which controls selection, ordering, or weighting of the output signals during combination.

In the illustrated embodiment, the combined output signal out_comb is further provided to the third frequency multiplication element 780, which multiplies a frequency of the combined output signal by a factor K to generate a frequency-multiplied output signal out_{comb}__{FM}. By distributing frequency scaling across the signal source path, the local oscillator paths, and the combined output path, the multiple-band BWE system 700 achieves scalable bandwidth extension and operating frequency translation while preserving phase correlation across multiple frequency bands.

Through coordinated operation of the phase correlator 750, the frequency multiplication elements, and the plurality of mixers 720-726, the multiple-band BWE system 700 enables generation of a continuous wideband chirp signal with improved phase noise performance using a single signal source. This distributed frequency multiplication and phase correlation framework relaxes design constraints on individual circuit blocks and facilitates implementation of the multiple-band BWE technique across a wide range of high-frequency, millimeter-wave, and sub-terahertz applications.

In some embodiments, the frequency multiplication factor M associated with the signal source path, the plurality of frequency multiplication factors N₁, N₂, N₃, …, N_{N-1} associated with the respective local oscillator paths, and the frequency multiplication factor K associated with the combined output path are positive integers greater than one and may be independently selected. The values of M, N₁…N_{N-1}, and K are not required to be equal and may be chosen based on target operating frequency ranges, bandwidth planning considerations, phase noise constraints, and implementation complexity of the corresponding circuit blocks.

In certain embodiments, the multiplication factors N₁…N_{N-1} applied to the local oscillator paths may be selected to be identical, such that the plurality of local oscillator signals is generated using a uniform frequency scaling relationship with respect to the phase-correlated control signal derived from the signal source. Such configuration may simplify local oscillator generation and facilitate consistent phase correlation behavior across multiple frequency conversion paths. In other embodiments, at least two of the multiplication factors N₁…N_{N-1} are selected to be different, allowing the frequency translation associated with each band to be independently optimized. For example, a larger multiplication factor may be applied to a local oscillator path corresponding to a higher-frequency band, while a smaller multiplication factor may be applied to another local oscillator path to reduce multiplication-induced phase noise or spurious components. As such, the system supports band-dependent frequency planning without requiring a single local oscillator architecture to satisfy all operating bands.

In some embodiments, the multiplication factors N₁…N_{N-1} may be arranged to follow a monotonic relationship across bands, such as progressively increasing or decreasing values, to accommodate structured placement of successive chirp segments toward higher or lower frequency regions. In other embodiments, the multiplication factors N₁…N_{N-1} may be selected in groups, such that multiple local oscillator paths share a common multiplication factor while other paths use different factors, thereby enabling reuse of frequency multiplication circuitry across subsets of bands while maintaining flexibility in overall band allocation.

The multiplication factor M applied to the signal source path may be selected to shift the base chirp signal to a preferred intermediate frequency range prior to frequency conversion, thereby reducing frequency translation requirements of the local oscillator paths. In some embodiments, a larger value of M may be selected to offload a greater portion of frequency scaling to the signal source path, while allowing smaller or moderate values of N₁…N_{N-1} to be used for local oscillator generation. In other embodiments, M may be selected to be relatively small to limit multiplication-induced phase noise on the signal source path, while relying on selected values of N₁…N_{N-1} to achieve desired band placement.

Separately, the multiplication factor K applied after the band combiner may be selected independently of M and N₁…N_{N-1} to perform final carrier frequency translation after multi-band signal assembly. By applying frequency multiplication after band combination, the system allows continuity of the wideband chirp signal to be established at a lower frequency stage, while subsequently translating the combined signal to a higher operating frequency band. Through coordinated selection of M, N₁…N_{N-1}, and K, the system distributes frequency scaling across the signal source path, the local oscillator paths, and the output path, thereby relaxing design trade-offs of individual circuit blocks and enabling scalable generation of wideband, phase-correlated chirp signals across multiple frequency bands.

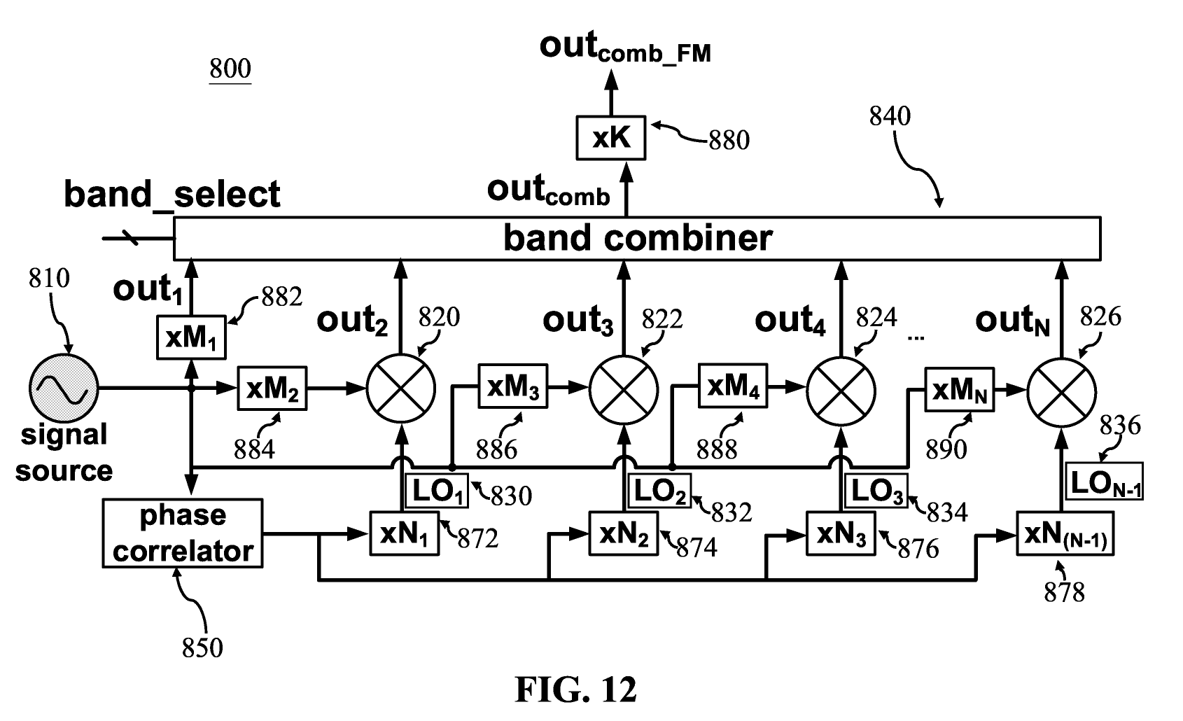

FIG. 12 illustrates a multiple-band BWE system 800 according to some embodiments of the present invention, in which pre-frequency multiplication, local oscillator multiplication, and post-frequency multiplication are jointly applied, and additional frequency scaling is introduced at inputs of the mixers. The multiple-band BWE system 800 includes a signal source 810, a phase correlator 850, a plurality of mixers 820, 822, 824, 826, a plurality of local oscillators (LO₁, LO₂, LO₃, …, LO_{N-1}) 830, 832, 834, 836, a band combiner 840, and a post-frequency multiplication element 880 configured to generate a frequency-multiplied combined output signal out_{comb}__{FM}.

In the illustrated embodiment, the signal source 810 is configured to generate a base chirp signal. The base chirp signal is provided to multiple signal paths through a plurality of frequency scaling elements 884, 886, 888, 890 (e.g., xM₂, xM₃, …, xM_{N}), which are respectively coupled between the signal source 810 and the inputs of the band combiner 840 or the mixers 820, 822, 824, 826. A first frequency scaling element xM₁ 882 may be coupled between the signal source 810 and the band combiner 840 to generate a low-band signal out₁, while additional frequency scaling elements 884, 886, 888, 890 (e.g., xM₂, xM₃, …, xM_{N}) are respectively coupled between the signal source 810 and corresponding mixers to generate mixer input signals for producing higher-band outputs out₂, out₃, out₄, …, out_{N}.

The frequency scaling factors M₁, M₂, M₃, …, M_{N} associated with the frequency scaling elements xM₁, xM₂, xM₃, …, xM_{N} may be independently selected. In some embodiments, one or more of the frequency scaling factors M₁-M_{N} are positive integers greater than one, such that frequency multiplication is performed prior to mixing. In other embodiments, one or more of the frequency scaling factors M₁-M_{N} may be fractional values smaller than one when implemented using frequency divider circuitry, thereby reducing an effective frequency presented to a corresponding mixer input. In still other embodiments, one or more of the frequency scaling factors M₁-M_{N} may be unity when implemented using buffer circuitry, such that the corresponding signal path preserves the original frequency of the signal source while providing isolation or signal conditioning. Through this configuration, each mixer input path may be independently tailored in frequency to support flexible band placement and frequency planning.

The phase correlator 850 is electrically coupled to receive a signal derived from the signal source 810 and is configured to generate phase-correlated control signals. These control signals are provided to a plurality of frequency multiplication elements 872, 874, 876, 878 (i.e., xN₁, xN₂, xN₃, …, xN_{N-1}), which apply respective multiplication factors N₁-N_{N-1} to generate corresponding local oscillator signals LO₁-LO_{N-1}. Each of the mixers 820, 822, 824, 826 is configured to perform frequency conversion using its corresponding local oscillator signal and its corresponding frequency-scaled input signal, thereby generating output signals out₂-out_{N} occupying different frequency bands.

The band combiner 840 is electrically coupled to receive the low-band signal out₁ and the plurality of frequency-converted signals out₂-out_{N} and is configured to combine the signals into a combined output signal out_{comb}. In some embodiments, the band combiner 840 further receives a band selection control signal band_select to control selection, ordering, or activation of the multiple band signals. The combined output signal out_{comb} is further provided to the post-frequency multiplication element 880, which applies a multiplication factor K to generate the frequency-multiplied output signal out_{comb}__{FM}.

By introducing independent frequency scaling at the mixer input paths through the frequency scaling elements xM₁-xM_{N}, the multiple-band BWE system 800 enables fine-grained control over frequency placement of individual bands prior to mixing. This configuration allows frequency translation burden, phase noise contribution, and spurious behavior to be distributed across the signal source path, the mixer input paths, the local oscillator paths, and the output path. As a result, the multiple-band BWE system 800 provides enhanced flexibility in multi-band frequency planning, relaxes design constraints of individual circuit blocks, and facilitates scalable generation of wideband, phase-correlated chirp signals across a wide range of operating frequencies.

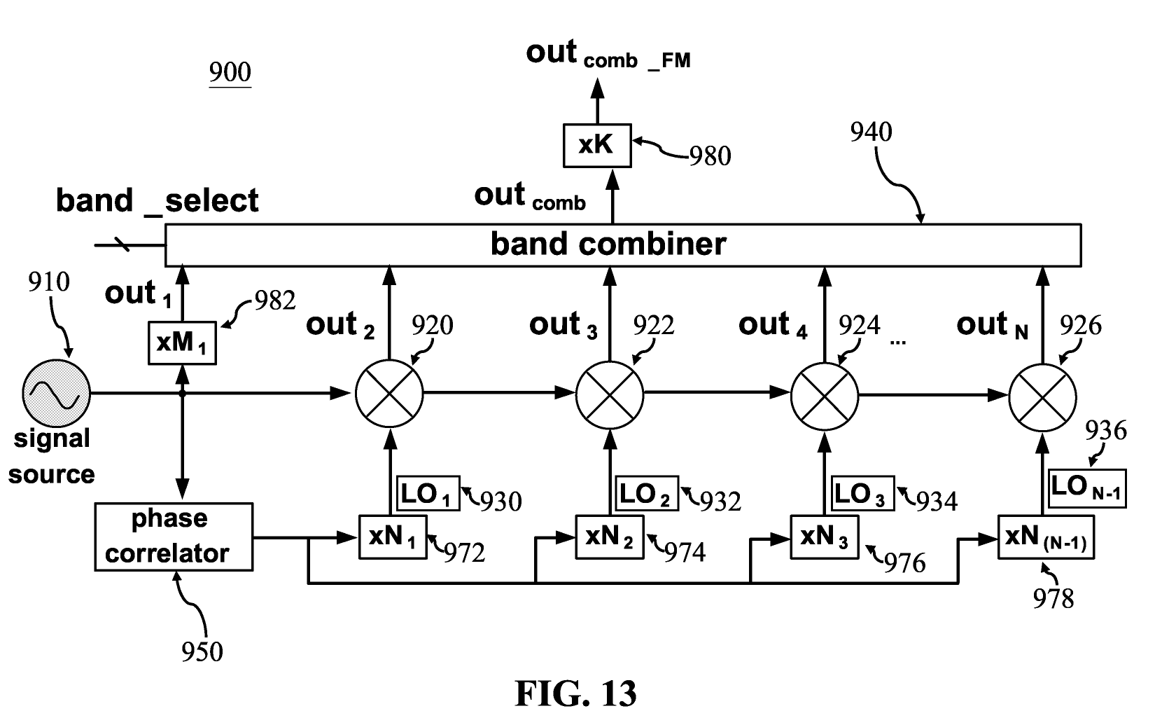

FIG. 13 illustrates a multiple-band BWE system 900 according to some embodiments of the present invention, in which pipeline mixers are employed to sequentially process a chirp signal across multiple frequency conversion stages. The multiple-band BWE system 900 includes a signal source 910, a phase correlator 950, a plurality of mixers 920, 922, 924, 926 arranged in a pipeline configuration, a corresponding plurality of local oscillators 930, 932, 934, 936 (LO₁, LO₂, LO₃, LO_{N-} ₁), a band combiner 940, and a post-frequency multiplication element 980 configured to generate a frequency-multiplied combined output signal out_{comb}__{FM}.

In the illustrated embodiment, the signal source 910 is configured to generate a base chirp signal, which may be frequency-scaled by a first frequency scaling element xM₁ 982 to generate a low-band signal out₁ that is provided to the band combiner 940. The base chirp signal is further supplied to a first mixer 920, which performs frequency conversion using a first local oscillator signal LO₁ to generate a second output signal out₂. Unlike the parallel mixer configurations described in previous embodiments, the output of the first mixer 920 is provided as an input to a subsequent mixer 922, which performs further frequency conversion using a second local oscillator signal LO₂ to generate a third output signal out₃. This pipelined processing continues through the further mixers 924 and 926, each receiving an input from a preceding mixer stage and generating a corresponding output signal out₄, …, out_{N}.

The phase correlator 950 is electrically coupled to receive a signal derived from the signal source 910 and is configured to generate phase-correlated control signals. These control signals are processed by a plurality of frequency multiplication elements 972, 974, 976, 978 (i.e., xN₁, xN₂, xN₃, …, xN_{N}) to generate corresponding local oscillator signals LO₁, LO₂, LO₃, LO_{N-1}. Through this configuration, phase-related variations of the signal source 910 are propagated along the pipeline of mixers, such that phase noise contributions introduced at successive frequency conversion stages remain correlated.

The band combiner 940 is electrically coupled to receive the low-band signal out₁ and the plurality of pipelined mixer output signals out₂, out₃, out₄, out_{N} and is configured to combine the signals into a combined output signal out_{comb}. In some embodiments, the band combiner 940 further receives a band selection control signal band_select to control which of the pipeline-generated signals are combined or output during particular time intervals. The combined output signal out_{comb} is further provided to the post-frequency multiplication element 980, which applies a multiplication factor K to generate the frequency-multiplied output signal out_{comb}__{FM}.

By employing pipelined mixers, the multiple-band BWE system 900 reuses frequency-converted signals generated at earlier stages as inputs to subsequent stages, thereby reducing duplication of signal routing and enabling structured progression of frequency translation across bands. This pipeline configuration supports scalable extension of the effective bandwidth while maintaining continuity of the chirp signal and preserving phase correlation across multiple frequency conversion stages. As a result, the system facilitates generation of wideband, phase-correlated chirp signals with improved scalability and implementation efficiency compared to architectures relying solely on parallel frequency conversion paths.

It should be understood that the bandwidth extension systems and architectures described with reference to FIGS. 4-13, although illustrated and discussed primarily in the context of chirp bandwidth extension, are not limited to a particular application or usage scenario. In various embodiments, any of the BWE systems disclosed herein may be implemented as, or incorporated within, a frequency synthesizer system configured to generate frequency-modulated signals over a desired operating frequency range.

The signal source, frequency conversion paths, and band combination mechanisms described in the BWE systems of FIGS. 4-13 collectively perform frequency generation, frequency translation, and bandwidth shaping functions that are characteristic of frequency synthesizer systems. Accordingly, the disclosed BWE systems may be regarded as frequency synthesizer systems, or as functional subsystems thereof, depending on system-level integration, application requirements, and operating modes. The term “frequency synthesizer system,” as used herein, is therefore intended to encompass the various BWE architectures described with reference to FIGS. 4-13 when configured to generate chirp signals or other frequency-modulated signals.

### Example

In one example implementation, the proposed dual-band bandwidth extension scheme may be implemented using an integrated circuit fabricated in a CMOS 28 nm process. In this example, an on-chip chirp signal source is configured to generate a chirp signal spanning from approximately 40.5 GHz to 49.5 GHz. By adopting a local oscillator signal at approximately 99 GHz, another chirp band may be generated through frequency mixing between the local oscillator signal and the chirp signal source, resulting in a higher-frequency chirp spanning from approximately 49.5 GHz to 58.5 GHz. After combining the low-band and high-band chirp signals by an on-chip band combiner, the overall chirp bandwidth is effectively expanded. In this example, a total bandwidth of approximately 18 GHz is obtained at the combined output.

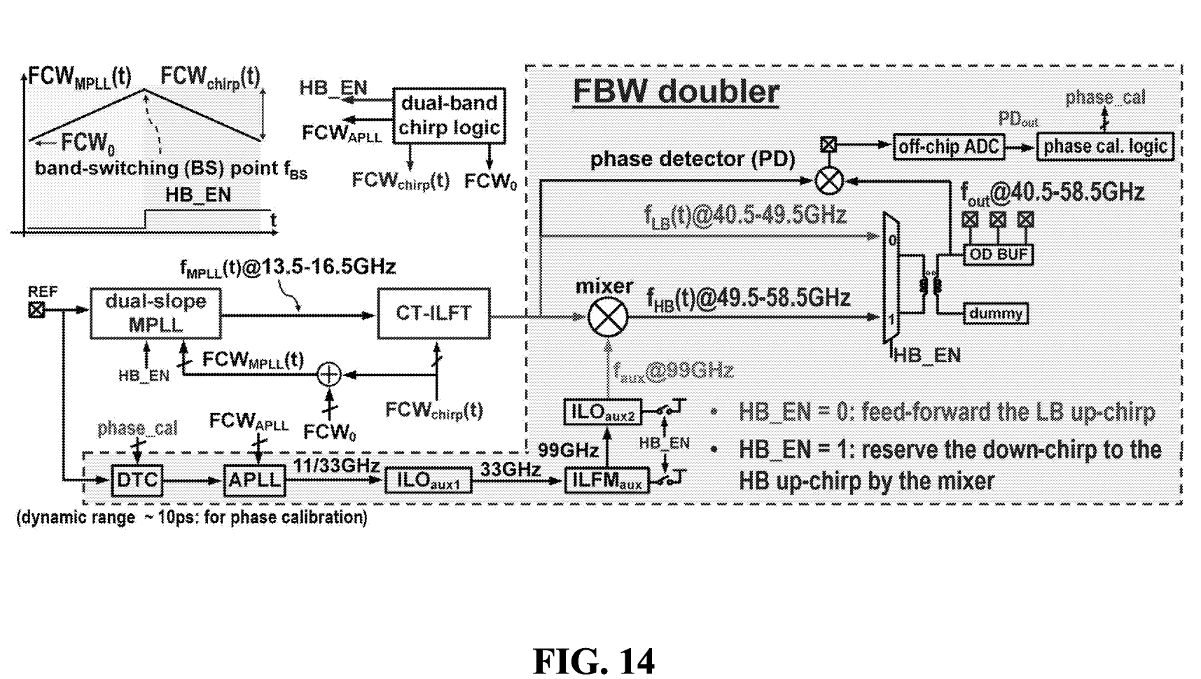

FIG. 14 shows an example of applying the proposed dual-band bandwidth extension technique in a chirp signal generation system. As illustrated, a chirp signal generated by a signal source is processed through a chirp generation and frequency translation path, and a frequency bandwidth (FBW) doubler is applied at an output of a CT-ILFT stage. The FBW doubler receives the chirp signal from the CT-ILFT output and performs bandwidth extension in accordance with the dual-band BWE principles described above.

In this example, the FBW doubler generates a low-band chirp and a high-band chirp through controlled frequency mixing and chirp polarity management, and combines the two bands to produce a chirp signal having an expanded effective bandwidth. The operation of the FBW doubler is coordinated by control logic, such that different chirp segments are selectively forwarded or frequency-converted to form a continuous wideband chirp signal. Through this configuration, the bandwidth extension is implemented at a system level without altering the underlying chirp signal generation mechanism.

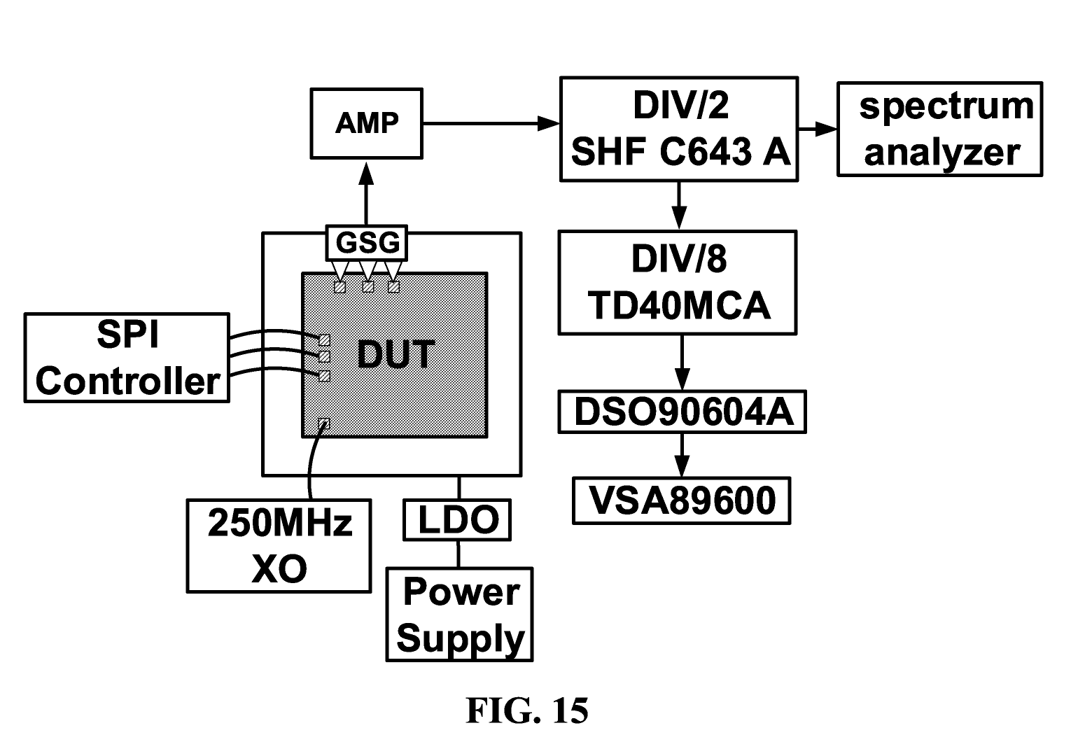

FIG. 15 shows an example measurement and evaluation configuration for characterizing an output chirp signal generated by the proposed bandwidth extension architecture. In this example, an output signal of a device under test (DUT) is amplified and coupled to one or more off-chip frequency divider stages. A divided-down version of the output chirp signal is supplied to an oscilloscope and further processed by a vector signal analysis tool to analyze chirp characteristics such as chirp rate and frequency linearity, while another divided version of the output signal is provided to a spectrum analyzer to observe spectral characteristics. The DUT is configured and controlled through a digital interface, and reference clock, power supply, and bias circuitry are provided to support operation during evaluation.

Using the above measurement configuration, the chirp signal generated by the DUT may be evaluated under different operating modes.

In one example configuration, a single-band chirp mode is enabled, in which a chirp signal is generated at the band combiner output with a chirp rate of approximately 2.2 GHz per microsecond, spanning a frequency range from approximately 40.5 GHz to 49.5 GHz, corresponding to an effective bandwidth of approximately 9 GHz, and exhibiting a chirp error of approximately 0.04%.

In another example configuration, a dual-band bandwidth extension mode is enabled, in which the chirp signal spans a frequency range from approximately 40.5 GHz to 58.5 GHz, corresponding to an effective bandwidth of approximately 18 GHz, while the chirp error is reduced to approximately 0.02%.

These example results demonstrate that the proposed dual-band BWE technique is capable of doubling the effective chirp bandwidth while improving chirp linearity at a fast chirp rate.

Moreover, in one example evaluation, a comparison is made between a single-band operating mode and a dual-band bandwidth extension operating mode during a measurement run, in order to illustrate performance differences before and after enabling the BWE technique. In the single-band configuration, the chirp signal spans a frequency range from approximately 40.5 GHz to 49.5 GHz, corresponding to an absolute bandwidth of approximately 9 GHz. In this configuration, the chirp rate is approximately 2.2 GHz per microsecond, with a root-mean-square (RMS) chirp error of approximately 0.04% and a peak chirp error of approximately 0.11%.

After enabling the dual-band BWE mode in the same evaluation, the chirp signal spans an expanded frequency range from approximately 40.5 GHz to 58.5 GHz, corresponding to an absolute bandwidth of approximately 18 GHz. While maintaining a similar chirp rate of approximately 2.2 GHz per microsecond, the chirp linearity is improved, with the RMS chirp error reduced to approximately 0.02% and the peak chirp error reduced to approximately 0.06%. This comparison illustrates that, within a single evaluation, the dual-band BWE mode provides both increased chirp bandwidth and improved chirp linearity relative to the single-band configuration.

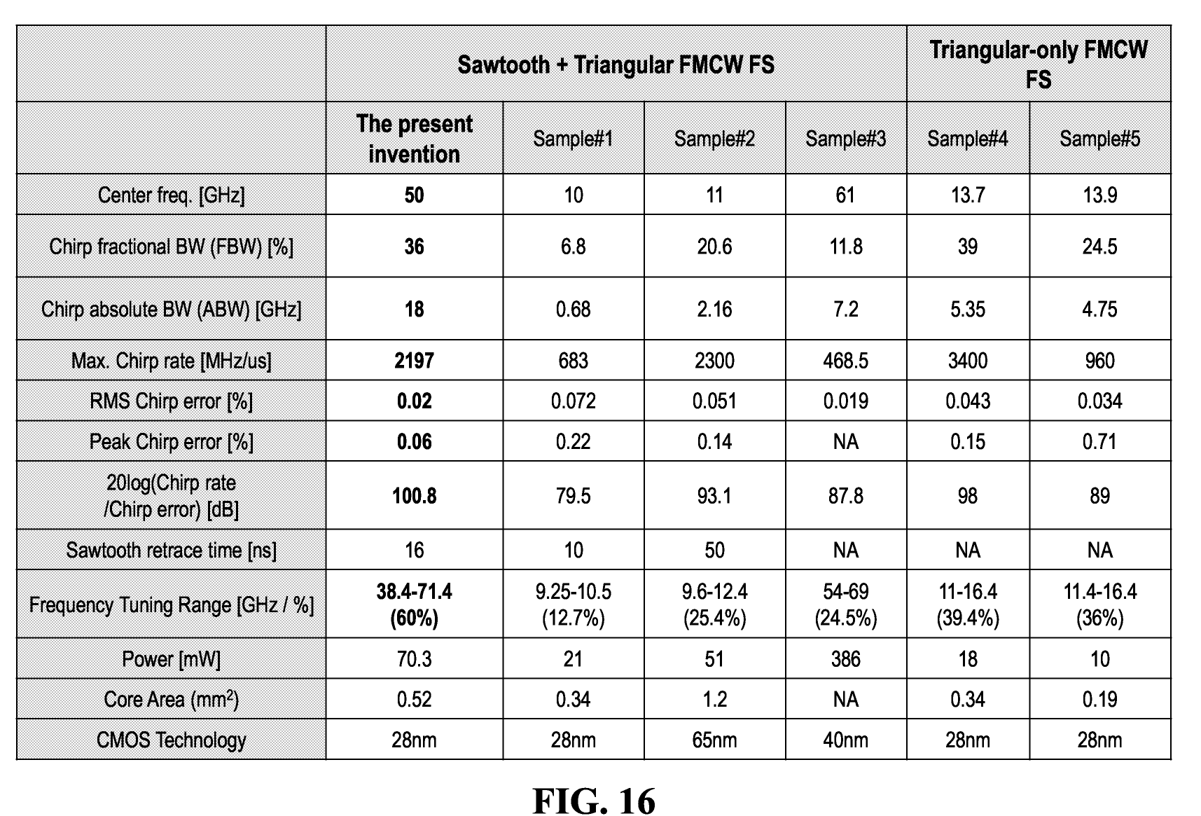

FIG. 16 shows a performance comparison between the architecture proposed in the present invention and representative sample implementations of other previously studied frequency synthesis and FMCW chirp generation approaches. The comparison summarizes key performance metrics, including operating frequency, chirp fractional bandwidth, chirp absolute bandwidth, chirp rate, chirp linearity, tuning range, power consumption, and implementation technology. The non-inventive entries in the table correspond to representative sample designs of existing solutions and are included solely to provide context for relative performance evaluation. As shown, the present invention achieves a wide absolute and fractional bandwidth together with a fast chirp rate and low chirp error, illustrating its overall performance characteristics in relation to other sample implementations.

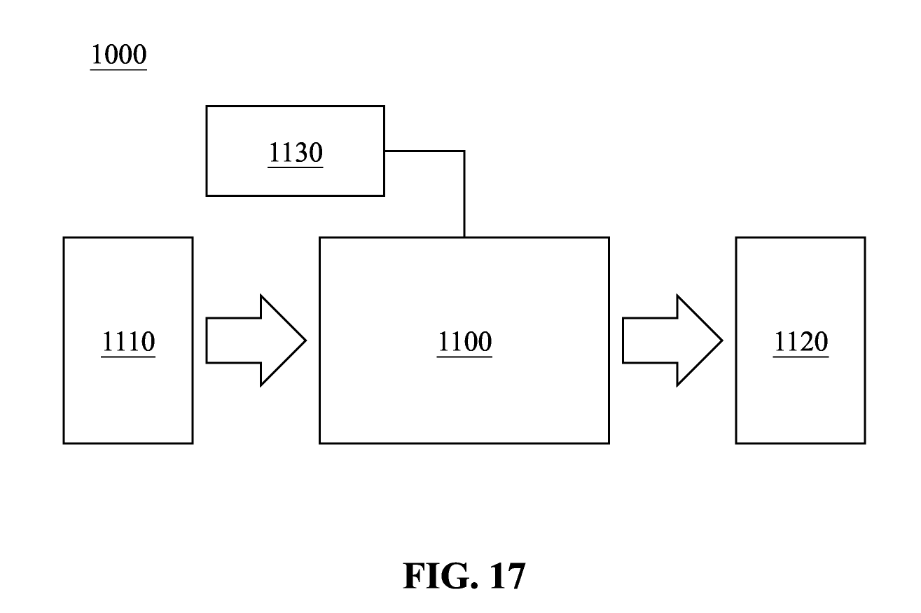

Although the foregoing embodiments describe configurations of individual bandwidth extension architectures, the disclosed techniques may be integrated to form a complete system suitable for practical applications under different usage scenarios. FIG. 17 shows an example signal generation and processing system according to some embodiments of the present invention.

The wideband chirp signal generation and processing system 1000 includes a bandwidth extension subsystem 1100, an upstream signal conditioning subsystem 1110 electrically coupled to an input of the bandwidth extension subsystem 1100, a downstream signal utilization subsystem 1120 electrically coupled to an output of the bandwidth extension subsystem 1100, and a control module 1130 electrically coupled to the bandwidth extension subsystem 1100.

The upstream signal conditioning subsystem 1110 is configured to provide input signals, reference signals, or configuration-related signals to the bandwidth extension subsystem 1100. The bandwidth extension subsystem 1100 is configured to generate a wideband chirp signal by performing bandwidth extension on a base chirp signal. The downstream signal utilization subsystem 1120 is configured to receive and process the wideband chirp signal for application-specific operations.

In various embodiments, the bandwidth extension subsystem 1100 may be implemented according to any of the dual-band or multiple-band bandwidth extension architectures described with reference to FIGS. 4-13. The bandwidth extension subsystem 1100 may include a signal source, one or more mixers, one or more local oscillators, and a band combiner, and is configured to generate a combined output signal having an extended fractional bandwidth and absolute bandwidth while maintaining chirp linearity.

The upstream signal conditioning subsystem 1110 may include one or more reference oscillators, clock generation circuits, frequency synthesis circuits, calibration circuits, or signal preprocessing circuits, and is configured to supply a base chirp signal or control-related signals used by the bandwidth extension subsystem 1100.

The downstream signal utilization subsystem 1120 may include one or more transmission circuits, reception circuits, radar front-end circuits, communication circuits, sensing circuits, or signal analysis circuits, and is configured to use the wideband chirp signal for applications such as radar sensing, ranging, imaging, or communication.

In some embodiments, the bandwidth extension subsystem 1100 includes a plurality of bandwidth extension architectures, each configured to perform bandwidth extension according to a different operating strategy. The plurality of bandwidth extension architectures may include, for example, one or more dual-band architectures, multiple-band architectures, frequency-multiplied architectures, phase-correlated architectures, or pipeline-based architectures as described with reference to FIGS. 4-13. These architectures may be implemented as separate functional units or as a shared reconfigurable circuit capable of operating in multiple modes.

In some embodiments, when the plurality of bandwidth extension architectures is integrated within the bandwidth extension subsystem 1100, one or more functional components may be shared among the plurality of bandwidth extension architectures. For example, a common signal source and/or a common band combiner may be utilized by multiple bandwidth extension architectures to generate and combine chirp signals under different operating strategies. In such configurations, the plurality of bandwidth extension architectures may reuse the same signal source to generate a base chirp signal and reuse the same band combiner to produce a combined output signal, while differing in intermediate processing stages such as frequency conversion, frequency multiplication, phase correlation, or pipeline configuration. This shared-component arrangement reduces hardware redundancy and facilitates compact integration while enabling flexible selection among different bandwidth extension architectures.

Correspondingly, the control module 1130 is configured to control one or more operating parameters of the bandwidth extension subsystem 1100 and to selectively activate, configure, or switch among the plurality of bandwidth extension architectures. The selection of a particular bandwidth extension architecture may be determined based on task requirements associated with the downstream signal utilization subsystem 1120, including but not limited to desired operating frequency range, bandwidth requirement, chirp rate, phase noise tolerance, power consumption constraint, or sensing or communication mode.

As such, the wideband chirp signal generation and processing system 1000 dynamically adapts bandwidth extension behavior in response to application-level requirements, allowing a common hardware platform to support multiple operational modes and use cases.

In summary, the present disclosure provides bandwidth extension architectures and a reconfigurable system for generating wideband chirp signals with high linearity at high operating frequencies. By combining base chirp signals with selectively configured frequency conversion and band combination techniques, the disclosed approaches enable simultaneous enhancement of fractional bandwidth and absolute bandwidth without significantly degrading chirp linearity. The disclosed system further supports multiple bandwidth extension architectures that may be dynamically selected and configured based on application requirements. Accordingly, the present disclosure enables flexible, scalable, and practical implementation of wideband chirp signal generation for a variety of sensing, communication, and signal processing applications.

The functional units and modules of the apparatuses and methods in accordance with the embodiments disclosed herein may be implemented using computing devices, computer processors, or electronic circuitries including but not limited to application specific integrated circuits (ASIC), field programmable gate arrays (FPGA), microcontrollers, and other programmable logic devices configured or programmed according to the teachings of the present disclosure. Computer instructions or software codes running in the computing devices, computer processors, or programmable logic devices can readily be prepared by practitioners skilled in the software or electronic art based on the teachings of the present disclosure.

All or portions of the methods in accordance to the embodiments may be executed in one or more computing devices including server computers, personal computers, laptop computers, mobile computing devices such as smartphones and tablet computers.

The embodiments may include computer storage media, transient and non-transient memory devices having computer instructions or software codes stored therein, which can be used to program or configure the computing devices, computer processors, or electronic circuitries to perform any of the processes of the present invention. The storage media, transient and non-transient memory devices can include, but are not limited to, floppy disks, optical discs, Blu-ray Disc, DVD, CD-ROMs, and magneto-optical disks, ROMs, RAMs, flash memory devices, or any type of media or devices suitable for storing instructions, codes, and/or data.

Each of the functional units and modules in accordance with various embodiments also may be implemented in distributed computing environments and/or Cloud computing environments, wherein the whole or portions of machine instructions are executed in distributed fashion by one or more processing devices interconnected by a communication network, such as an intranet, Wide Area Network (WAN), Local Area Network (LAN), the Internet, and other forms of data transmission medium.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. A frequency synthesizer system, comprising:
a signal source configured to generate a chirp signal having a limited tuning range;
at least one mixer configured to receive the chirp signal from the signal source and a local oscillator signal, and to perform frequency conversion on the chirp signal to generate a frequency-converted chirp signal;
at least one local oscillator configured to generate the local oscillator signal supplied to the mixer; and
a band combiner electrically coupled to receive:
a first chirp signal derived from the signal source without being processed by the mixer; and
a second chirp signal generated by the mixer through frequency conversion of the chirp signal, wherein the band combiner is further configured to combine the first chirp signal and the second chirp signal to generate a combined output chirp signal having an extended effective bandwidth relative to the chirp signal generated by the signal source.

2. The frequency synthesizer system of claim 1, further comprising:
a phase correlator electrically coupled to the signal source and the local oscillator and configured to generate a phase-correlated control signal based on the chirp signal generated by the signal source and to supply the phase-correlated control signal to the local oscillator, such that phase variations associated with the signal source are correlated with phase variations of the local oscillator during frequency conversion performed by the mixer.

3. The frequency synthesizer system of claim 2, further comprising:
a first frequency multiplication element coupled between the signal source and the band combiner and configured to multiply a frequency of the chirp signal by a first multiplication factor to generate the first chirp signal; and
a second frequency multiplication element coupled to process the phase-correlated control signal generated by the phase correlator and configured to multiply the phase-correlated control signal by a second multiplication factor to generate a frequency-multiplied local oscillator signal supplied to the mixer, wherein the mixer is further configured to perform frequency conversion using the frequency-multiplied local oscillator signal to generate the second chirp signal.

4. The frequency synthesizer system of claim 3, wherein the first multiplication factor and the second multiplication factor are different positive integers.

5. The frequency synthesizer system of claim 3, further comprising:
a post-frequency multiplication element coupled to an output of the band combiner and configured to multiply a frequency of the combined output chirp signal by a third multiplication factor.

6. The frequency synthesizer system of claim 5, wherein the third multiplication factor is greater than the first multiplication factor and the second multiplication factor, such that a majority of frequency scaling is performed after low-band and high-band chirp signals are combined by the band combiner.

7. The frequency synthesizer system of claim 1, further comprising:
a post-frequency multiplication element coupled to an output of the band combiner and configured to multiply a frequency of the combined output chirp signal by a multiplication factor, such that an operating frequency of the combined output chirp signal is increased without altering continuity of the chirp signal generated by the band combiner.

8. The frequency synthesizer system of claim 1,
wherein the frequency synthesizer system comprises a plurality of mixers and a corresponding plurality of local oscillators,
wherein the signal source is configured to supply the chirp signal to the plurality of mixers,
wherein each of the mixers is configured to receive the chirp signal and a corresponding local oscillator signal and to perform frequency conversion to generate a respective frequency-converted chirp signal occupying a different frequency band,
and wherein the band combiner is electrically coupled to receive the first chirp signal and the respective frequency-converted chirp signals generated by the mixers and is configured to combine the first chirp signal and the respective frequency-converted chirp signals to generate the combined output chirp signal having an extended effective bandwidth.

9. The frequency synthesizer system of claim 8, further comprising:
a phase correlator electrically coupled to the signal source and configured to generate phase-correlated control signals based on the chirp signal generated by the signal source;
a first frequency multiplication element coupled to the signal source and configured to multiply a frequency of the chirp signal by a first multiplication factor prior to being supplied to the mixers;
a plurality of second frequency multiplication elements configured to respectively multiply the phase-correlated control signals by a plurality of second multiplication factors to generate corresponding local oscillator signals supplied to the mixers; and
a third frequency multiplication element coupled to an output of the band combiner and configured to multiply a frequency of the combined output chirp signal by a third multiplication factor,
wherein the mixers are further configured to perform frequency conversion using the frequency-multiplied chirp signal and the corresponding frequency-multiplied local oscillator signals to generate a plurality of frequency-converted chirp signals occupying different frequency bands that are combined by the band combiner.

10. The frequency synthesizer system of claim 9, wherein at least two of the second multiplication factors are different from each other.

11. The frequency synthesizer system of claim 9, further comprising:
a plurality of frequency scaling elements respectively coupled between the signal source and corresponding inputs of the plurality of mixers, wherein each of the frequency scaling elements is configured to apply a respective frequency scaling factor to the chirp signal supplied to the corresponding mixer, such that frequency scaling applied to the chirp signal is independently configurable for different mixer input paths prior to the frequency conversion.

12. The frequency synthesizer system of claim 11, wherein the respective frequency scaling factors applied by the frequency scaling elements are not all identical.

13. The frequency synthesizer system of claim 9, wherein the mixers are arranged in a pipeline configuration such that an output of at least one mixer is supplied as an input to a subsequent mixer, wherein the mixers are configured to perform frequency conversion in successive stages using corresponding local oscillator signals, such that the chirp signal undergoes sequential frequency conversion across multiple mixer stages prior to being supplied to the band combiner.

14. A wideband signal generation and processing system, comprising:
a plurality of frequency synthesizer systems according to claim 1; and
a control module configured to control operation of the frequency synthesizer systems, wherein the frequency synthesizer systems are selectively operated to generate one or more chirp signals in accordance with different operating modes or requirements.

15. The wideband signal generation and processing system of claim 14, wherein the frequency synthesizer systems include different types comprising at least two of:
frequency synthesizer systems incorporating frequency multiplication applied to a chirp signal prior to frequency conversion;
frequency synthesizer systems incorporating frequency multiplication applied to a local oscillator signal supplied to a mixer; and
frequency synthesizer systems incorporating frequency multiplication applied to a combined output chirp signal after band combination.

16. The wideband signal generation and processing system of claim 15, wherein at least two different types of the frequency synthesizer systems share one or more common functional components comprising at least one of a common signal source and a common band combiner.

17. A method of operating a frequency synthesizer system, comprising:
generating, by a signal source, a chirp signal having a limited tuning range;
supplying the chirp signal along a first signal path directly to a band combiner as a first chirp signal without frequency conversion;
supplying the chirp signal along a second signal path to a mixer;
generating, by a local oscillator, a local oscillator signal supplied to the mixer;
performing, by the mixer, frequency conversion on the chirp signal using the local oscillator signal to generate a second chirp signal; and
combining, by the band combiner, the first chirp signal and the second chirp signal to generate a combined output chirp signal having an extended effective bandwidth relative to the chirp signal generated by the signal source.

18. The method of claim 17, further comprising:
prior to supplying the chirp signal to the mixer, multiplying a frequency of the chirp signal by a first multiplication factor, wherein the frequency-multiplied chirp signal is supplied to the mixer for performing the frequency conversion.

19. The method of claim 18, further comprising:
prior to performing the frequency conversion, multiplying a frequency of the local oscillator signal by a second multiplication factor, wherein the frequency-multiplied local oscillator signal is supplied to the mixer for performing the frequency conversion on the chirp signal.

20. The method of claim 19, further comprising:
after combining the first chirp signal and the second chirp signal, multiplying a frequency of the combined output chirp signal by a third multiplication factor to generate a frequency-multiplied output chirp signal.
